(19) United States
(12) Patent Application Publication
(10) Pub. No.: US 2024/0280899 A1
(43) Pub. Date: Aug. 22, 2024

(54) FABRICATION OF EUV MASKS USING A COMBINATION OF MONOLAYER LITHOGRAPHY AND AREA SELECTIVE DEPOSITION

(71) Applicant: International Business Machines Corporation, Armonk, NY (US)

(72) Inventors: Rudy J. Wojtecki, San Jose, CA (US); Nelson Felix, Slingerlands, NY (US); Krystelle Lionti, San Jose, CA (US); Noel Arellano, Gilroy, CA (US)

(21) Appl. No.: 18/112,803

(22) Filed: Feb. 22, 2023

(51) Int. Cl. G03F 7/004; G03F 7/16; G03F 7/20

(52) U.S. Cl. CPC G03F 7/0045; G03F 7/165; G03F 7/2016

(57) ABSTRACT

A surfactant or photoacid generator (PAG) that forms a self-assembled monolayer is deposited on a substrate surface. Application of electron beam (e-beam) and/or extreme ultraviolet (EUV) radiation to the substrate surface forms a negative or positive tone pattern on the monolayer. A hydroxamic acid may be used to form a negative tone self-assembled monolayer and a silane or PAG may be used to form a positive tone self-assembled monolayer. Area selective deposition of an EUV absorbing material on the negative or positive tone patterned monolayer forms a negative or positive tone EUV absorbing mask, respectively.

### TECHNICAL FIELD

The present invention relates generally to extreme ultraviolet (EUV) masks fabricated with a combination of monolayer lithography and area selective deposition and more specifically to EUV masks fabricated through the lithographic patterning of a self-assembled monolayer on a substrate surface and the area selective deposition of an EUV absorbing material onto the patterned monolayer.

### BACKGROUND OF THE INVENTION

High numerical aperture (NA) EUV lithography has two EUV absorber requirements: a contrast of >85% and a thickness of <30 nm. Two examples of materials that meet the high NA EUV lithography requirements are platinum (Pt) and tellurium (Te); however, these two materials are not suitable for conventional EUV patterning, which requires the generation of volatile species in order to pattern with etching; consequently, etch resistant materials, such as Pt and Te cannot be used in conventional EUV patterning. Currently, EUV mask fabrication requires patterning via conventional deposition and etching with the absorber tantalum nitride (TaN). TaN has a contrast of approximately 75% contrast and a thickness of >60 nm; thus, it does not meet the requirements for high NA EUV lithography. In order to achieve high NA EUV lithography, EUV mask fabrication needs to evolve beyond the currently used absorber materials and/or conventional techniques.

### SUMMARY OF THE INVENTION

The present invention overcomes the need in the art by providing a method of EUV mask fabrication that does not require etching and thus, allows for the application of etch resistant absorbers that meet the requirements high NA EUV lithography.

In one embodiment, the present invention relates to a composition comprising: a substrate with a top surface and a bottom area; a self-assembled monolayer adhered to the top surface of the substrate, wherein the self-assembled monolayer comprises a surfactant or a photoacid generator; and an EUV absorbing film comprising at least one EUV absorbing material, wherein the EUV absorbing material binds to the self-assembled monolayer in a negative or positive tone pattern.

In another embodiment, the present invention relates to a method for fabricating a positive or negative EUV mask comprising: depositing a surfactant or a photoacid generator on a substrate, wherein the surfactant and/or photoacid generator self-aligns on a surface of the substrate to form a monolayer; exposing the monolayer to patternwise e-beam or EUV radiation to form a resist pattern; and depositing an EUV absorbing material onto the monolayer wherein the EUV absorbing material binds to unexposed areas of the monolayer to form a negative patterned EUV mask or exposed areas of the monolayer to form a positive patterned EUV mask.

In a further embodiment, the present invention relates to a method for fabricating a negative tone EUV mask comprising: depositing a hydroxamic acid comprising a polar head group and a non-polar tail on a substrate comprising a metal surface, wherein the hydroxamic acid self-aligns to form a monolayer via reaction of the polar head group of the hydroxamic acid with the metal surface of the substrate; exposing the monolayer to pattern-wise e-beam or EUV radiation, wherein regions of the monolayer exposed to the e-beam or EUV radiation are crosslinked and regions not exposed to the e-beam or EUV radiation are uncrosslinked; and depositing an EUV absorbing material onto the monolayer, wherein the EUV absorbing material binds to the non-polar tail of the hydroxamic acid on the unexposed and uncrosslinked regions of the monolayer to form a negative tone EUV mask.

In another embodiment, the present invention relates to a method for fabricating a positive tone EUV mask comprising: depositing a silane on a substrate, wherein the silane has head groups that are reactive and tails that are non-reactive and the silane self-aligns to form a monolayer via reaction of the head groups to a top surface of the substrate; treating the monolayer with pattern-wise e-beam or EUV radiation, wherein the e-beam or EUV radiation activates the tails of the silane through generation of a polar group on the tails of the silane only in regions of the monolayer exposed to the e-beam or EUV radiation; and depositing an EUV absorbing material onto the treated monolayer, wherein the EUV absorbing material binds to the polar group of the silane tails to form a positive tone EUV mask.

In a further embodiment, the present invention relates to a method for fabricating a positive tone EUV mask comprising: depositing a photoacid generator (PAG) on a substrate, wherein the PAG has head groups that are reactive and tails groups that are non-reactive and the PAG self-aligns to form a polymer brush monolayer via reaction of the head groups to a top surface of the substrate; treating the PAG with patternwise e-beam or EUV radiation, wherein the e-beam EUV radiation activates the tail groups of the PAG through generation of a polar acid on the tail groups of the PAG only in regions of the polymer brush monolayer exposed to the e-beam or EUV radiation; and depositing an EUV absorbing material onto the treated polymer brush monolayer, wherein the EUV absorbing material binds to the polar acid of the PAG tail groups to form a positive tone EUV mask.

In another embodiment, the substrate is a metal capped substrate and the surfactant has 3-24 C atoms, a polar head group that chelates to the metal cap of the substrate, and a non-polar tail that binds the EUV absorbing material in a negative tone pattern.

In a further embodiment, the metal surface of the substrate is selected from the group consisting of ruthenium, palladium, platinum, titanium, tantalum, nickel, copper, aluminum, and combinations thereof.

In another embodiment, the surfactant is an organosilicon compound with a reactive head that adheres to the substrate and a polar tail that binds the EUV absorbing material in a positive tone pattern.

In a further embodiment, the EUV absorbing material is selected from the group consisting of platinum, tellurium, zinc, titanium, antimony, indium, bismuth, silver, and combinations thereof.

In another embodiment, the self-assembled monolayer has crosslinked and non-crosslinked regions, wherein the EUV absorbing material only adheres to the non-crosslinked regions of the self-assembled monolayer in a negative tone pattern.

In a further embodiment, the crosslinked regions of the monolayer are removed from the negative tone EUV mask with a reducing agent selected from the group consisting of H₂ plasma, N₂ plasma, NH₃ plasma, and combinations thereof.

In another embodiment, the negative tone of the EUV mask is enhanced with a compound selected from the group consisting of phosphonic acid, phosphonic acid derivatives, stearic acid, stearic acid derivatives, and combinations thereof.

In a further embodiment, the hydroxamic acid is selected from the group consisting of unsubstituted hydroxamic acid, methyl-hydroxamic acid, tetra-hydroxamic acid, hexyl-hydroxamic acid, octyl-hydroxamic acid, cyclohexyl-hydroxamic acid, octadecyl-hydroxamic acid, dodecyl-hydroxamic acid, and combinations thereof.

In another embodiment, the hydroxamic acid further comprises reactive groups selected from the group consisting of alkenes, alkynes, glycidyls, and combinations thereof.

In a further embodiment, the silane is selected from the group consisting of aminosilanes, ethoxysilanes, chlorosilanes, glycidoxysilanes, methacryloxysilanes, methoxysilanes, N-alkyl-silanes, mercaptosilanes, and combinations thereof.

In another embodiment, the PAG is a polymer brush with a reactive head that adheres to the substrate and a polar tail that binds the EUV absorbing material in a positive tone pattern.

In a further embodiment, the PAG is an ionic PAG selected from the group consisting of diaryliodonium salts, triarylsulfonium salts, and naphthalimide sulfonates, and combinations thereof.

In another embodiment, the PAG is a non-ionic PAG selected from the group consisting of iminosulfonates, imidosulfonates, benzyl sulfonates, and combinations thereof.

Additional aspects and/or embodiments of the invention will be provided, without limitation, in the detailed description of the invention that is set forth below.

### BRIEF DESCRIPTION OF THE DRAWINGS

FIG. 1 is a schematic diagram showing the fabrication of a negative tone EUV mask.

FIG. 2 is a schematic diagram showing application of different surfaces for the fabrication of negative tone EUV masks.

FIG. 3 is a contrast curve graph for two negative tone zinc oxide (ZnO) EUV masks, one fabricated with a self-assembled monolayer (SAM) of unsubstituted hydroxamic acid and the other with a SAM of methyl-hydroxamic acid and ZnO.

FIG. 4 is graph showing the exposure results of atomic layer deposition (ALD) of the EUV absorber ZnO on two negative tone resists, one fabricated with a SAM of unsubstituted hydroxamic acid and the other with a SAM of methyl-hydroxamic acid.

FIG. 5 is a graph showing the exposure results of ALD of ZnO on three negative tone resists, one fabricated with a SAM of unsubstituted hydroxamic acid, the other with a SAM of methyl-hydroxamic acid, and the third with a SAM of cyclohexyl-hydroxamic acid.

FIG. 6 show Rutherford backscattering spectroscopy (RBS) contrast curves at EUV dosages of 0-205 mJ/cm² applied to three ZnO negative tone EUV masks, one prepared with a SAM of unsubstituted hydroxamic acid, the other with a SAM of methyl-hydroxamic acid, and the third with a SAM of cyclohexyl-hydroxamic acid.

FIG. 7 shows x-ray photoelectron spectroscopy (XPS) contrast curves at EUV dosages of 1-205 mJ/cm² applied to three ZnO negative tone EUV masks, one prepared with a SAM of cyclohexyl-hydroxamic acid, the other with of phosphonic acid, and the third with octadecanethiol (ODT).

FIG. 8 is a schematic illustration of the different packing densities of hydroxamic acid, methyl-hydroxamic acid, and cyclohexyl-hydroxamic acid.

FIG. 9 is a schematic illustration of how phosphonic acid increases the contrast of a hydroxamic acid SAM during area selective deposition.

FIG. 10 schematically illustrates the fabrication of a positive tone EUV mask with a silane SAM upon a substrate.

FIG. 11 is a contrast curve graph for two positive tone titanium dioxide (TiO₂) masks, one fabricated with 50 mol % trichlorophenylsilane (TPS) and the other with 10 mol % TPS.

FIG. 12A is a diagram of a non-ionic PAG and FIG. 12B is a diagram of a polymer incorporating the non-ionic PAG.

FIGS. 13A-13C are contrast curves for SAM of the non-ionic PAG of FIG. 12B at 193 nm exposure pre- and post-development (FIG. 13A), 248 nm exposure pre- and post-development (FIG. 13B), and EUV exposure post-development (FIG. 13C).

### DETAILED DESCRIPTION OF THE INVENTION

Set forth below is a description of what are currently believed to be preferred aspects and/or embodiments of the claimed invention. Any alternates or modifications in function, purpose, or structure are intended to be covered by the appended claims. As used in this specification and the appended claims, the singular forms “a,” “an,” and “the” include plural referents unless the context clearly dictates otherwise. The terms “comprise,” “comprised,” “comprises,” and/or “comprising,” as used in the specification and appended claims, specify the presence of the expressly recited components, elements, features, and/or steps, but do not preclude the presence or addition of one or more other components, elements, features, and/or steps.

As used herein, the terms “photolithography” and “lithography” refer to the fabrication of a minutely patterned thin film over a substrate in order to protect selected areas of the substrate during microchip fabrication.

As used herein, the term “EUV lithography” refers to lithography that uses light with a wavelength of 13.5 nm.

As used herein, the term “EUV radiation” refers to light that has photons with energies ranging from 10 eV to 124 eV and wavelengths ranging from 10 nm to 100 nm.

As used herein, the term “electron-beam radiation” or “e-beam radiation” refers to the delivery of high energy electrons via an electron-beam accelerator, to a material in order to induce changes in a material, such as crosslinking.

As used herein, the term “EUV mask” refers to a photolithography thin film that has (i) a EUV absorbing layer deposited atop multiple layers of an EUV substrate material (e.g., 40-50 layers of molybdenum and silicon); (ii) a pattern defined on the EUV absorbing layer; and (iii) a surface that reflects light off of the patterned areas of the EUV absorbing layer. Because EUV masks are made out of reflective surfaces and light-blocking elements that produce a pattern upon exposure to ultraviolet radiation (which can be e-beam and/or EUV radiation), they are different from traditional photolithography masks, the latter of which are opaque films or plates with holes or transparent areas that allow light to shine through in a defined pattern. The EUV masks described herein may be negative or positive tone.

As used herein, the term “substrate” refers to the base material upon which a processing is conducted.

As used herein, the term “self-assembled monolayer,” and “SAM” refers to a one molecule thick layer of material that bonds to a substrate surface in an ordered way as a result of physical or chemical forces during a deposition process.

As used herein, the term “resist” refers to the layers that are applied to a substrate. Within the context of the present invention, the term “resist” is used to denote the layers on a substrate that will ultimately be transformed to an EUV mask upon deposition of an EUV absorber on a self-assembled monolayer on a substrate.

As used herein, the term “area selective deposition” of “ASD” refers to a bottom-up process leading to a uniform deposition in selected areas of a patterned substrate. Within the context of the present invention, area selective deposition used to deposit an EUV absorber onto an EUV substrate, the latter of which has a surfactant monolayer on a top surface.

As used herein, the term “chemical vapor deposition” or “CVD” refers to a method of area selective deposition that uses a vacuum to produce thin films. With CVD, a substrate is exposed to one or more volatile precursors, which react and/or decompose on the substrate surface to deposit a material. With CVD, volatile by-products may be produced, which are typically removed by gas flow through a reaction chamber. Within the context of the present invention, CVD may be used for area selective deposition of an EUV absorber on an EUV mask.

As used herein, the term “atomic layer deposition” or “ALD” refer to a method of area selective deposition that uses a gas-phase chemical process to produce thin films. ALD is considered to be a subclass of CVD. ALD reactions use two gaseous precursor chemicals that react with the substrate surface one at a time in a sequential non-overlapping manner. In this way, a thin film is slowly deposited through repeated exposure to separate precursors. Unlike CVD, the ALD precursors are never present simultaneously. Within the context of the present invention, ALD may be also be used for area selective deposition of an EUV absorber on an EUV mask. Within the context of the present invention, examples of materials that may be used for ALD include zinc oxide (ZnO), platinum (Pt), titanium dioxide (TiO₂), or tellurium (Te).

Described herein is an additive approach for the fabrication of high NA EUV masks through pattern-wise growth of an EUV absorber on a surfactant treated substrate where the surfactant is a self-assembled monolayer that is patternable. The additive approach enables the pattern-wise addition of strong EUV absorbing films, such as Pt and/or Te films, that are difficult to pattern using conventional deposition and etching techniques. The EUV absorbing material may be deposited onto the surfactant treated substrate through the area selective deposition methods of CVD or ALD with no damage the underlying substrate. The combination of the patternable surfactant monolayer and the area selective deposition of the EUV absorber allows for the fabrication of customized EUV masks. Because the additive approach does not require an etch step, the additive approach allows for the fabrication of EUV masks with highly etch resistant absorbers such as Pt and/or Te. Fabrication of the EUV masks described herein thus use a combination of monolayer lithography and area selective deposition where the monolayer lithography patterns a surfactant self-assembled monolayer on the substrate surface and area the EUV mask is fabricated via selective are deposition of an EUV absorber on the patterned surfactant monolayer.

In one embodiment, the high NA EUV absorber comprises a chemical selected from the group consisting of platinum (Pt), tellurium (Te), zinc (Zn), titanium (Ti), antimony (SB), indium (In), bismuth (Bi), silver (Ag), and combinations thereof.

In another embodiment, the surfactants used to form the self-assembled monolayer have 3-42 carbon atoms. In another embodiment, the surfactant has a polar head group and a non-polar tail group. In a further embodiment, the surfactant has reactive side groups that assist in the self-assembly of the surfactant into a monolayer. Such reactive side groups include, without limitation, alkenes, alkynes, glycidyls, and combinations thereof. Examples of surfactants that may be used to form the self-assembled monolayers include, without limitation, hydroxamic acid and derivatives thereof (referred to collectively herein as “hydroxamic acids”), silane and derivatives thereof (referred to herein as “silanes”), and photoacid generators (PAGs).

Hydroxamic acids are a class of organic compounds with the formula RC(O)N(OH)R′ where CO is a carbonyl group, R is an organic residue and R′ is. Hydroxamic acids generally are comprised of a polar hydroximic head group, a hydrophobic methylene spacer, a second polar site, and a terminal non-polar hydrophobic group. Within the context of the present invention, the polar head of hydroxamic acids bind strongly to the metal ions on the surface of the substrate material to form a self-assembled monolayer. Upon exposure to e-beam and/or EUV radiation, the iron-chelated polar heads of the hydroxamic acids crosslink. The EUV absorber covalently binds to the non-polar tail of the hydroxamic acids upon ALD or CVD. Hydroxamic acids that may be used for the self-assembled monolayer described herein may be substituted or unsubstituted. Examples of hydroxamic acids include, without limitation, unsubstituted hydroxamic acid, methyl-hydroxamic acid, n-butyl-hydroxamic acid, n-hexyl-hydroxamic acid, n-octyl-hydroxamic acid, cyclohexyl-hydroxamic acid, octadecyl-hydroxamic acid, dodecyl-hydroxamic acid, and combinations thereof. Example 1 describes a negative tone EUV mask fabricated with a hydroxamic acid self-assembled monolayer.

Silanes are a class of charge-neutral silicon compounds with the formula SiₙR₂ₙ₊₂, where n=1, 2, 3, 4, etc. and the R substituent may be a combination or organic or inorganic groups. Most silanes are organosilicon compounds that contain Si—C bonds. Silanes for use as self-assembled monolayers are generally comprised of a reactive head group comprising the silicon and a non-reactive tail. Within the context of the present invention, the reactive head of the silanes bind to any suitable substrate surface to form a self-assembled monolayer. Upon exposure to e-beam and/or EUV radiation followed by exposure to oxygen, the non-reactive tail of the silane becomes reactive and chemically binds with the oxygen transforming the silane tail to a reactive polar group comprising at least one hydroxy (—OH) and/or carbonyl (—COOH) group. Examples of silanes that may be used for the self-assembled monolayer described herein include, without limitation, aminosilanes, ethoxysilanes, chlorosilanes, glycidoxysilanes, methacryloxysilanes, methoxysilanes, N-alkyl-silanes, mercaptosilanes, and combinations thereof. Example 2 describes a positive tone EUV mask fabricated with a silane self-assembled monolayer.

PAGS are organic compounds that decompose and generate protons (H⁺) (i.e., produce polar acids) upon irradiation with wavelengths of light. PAGs are classified into two groups: ionic PAGs and non-ionic PAGs. Examples of ionic PAGs including, without limitation, diaryliodonium salts, triarylsulfonium salts, and naphthalimide sulfonates, and combinations thereof. Examples of non-ionic PAGs include, without limitation, iminosulfonates, imidosulfonates, benzyl sulfonates, and combinations thereof. Example 3 describes a positive tone EUV mask fabricated with a silane self-assembled monolayer.

In one embodiment, the EUV mask has a negative tone, hydroxamic acids are used for the self-assembled monolayer, and e-beam and/or EUV radiation is used for the patterning. The formation of the pattern occurs via pattern-wise e-beam and/or EUV radiation where the exposed areas of the surfactant treated SAM are crosslinked while the non-exposed areas are not crosslinked. When the EUV absorber is deposited onto the treated and irradiated SAM, the EUV absorber grows only on the areas of the treated SAM that have not been exposed to the e-beam and/or EUV radiation.

In another embodiment, after e-beam and/or EUV exposure and prior to deposition of the EUV absorbing material, the hydroxamic acid monolayer is treated or replaced with a contrast enhancing agent. Examples of contrast enhancing materials that may be applied to the surfactant monolayer include, without limitation, phosphonic acid, phosphonic acid derivatives, stearic acid, stearic acid derivatives, and combinations thereof.

In a further embodiment, the crosslinked regions of the hydroxamic acid monolayer are removed from the EUV mask substrate with a reducing agent selected from the group consisting of H₂ plasma, N₂ plasma, NH₃ plasma, and combinations thereof.

In another embodiment, the substrate for the negative tone EUV mask is capped with a metal selected from the group consisting of ruthenium, palladium, platinum, titanium, tantalum, nickel, copper, aluminum, and combinations thereof. In a further embodiment, the substrate for the negative tone EUV mask comprises silicon, silicon dioxide, beryllium, molybdenum, and combinations thereof. In another embodiment, the substrate is a multilayer thin film comprising silicon, silicon dioxide, beryllium, molybdenum, and combinations thereof. In a further embodiment, the substrate is a multilayer thin film comprising molybdenum silicon (Mo/Si) or molybdenum beryllium (Mo/Be). In another embodiment, the substrate is planar. In a further embodiment, the substrate is coplanar.

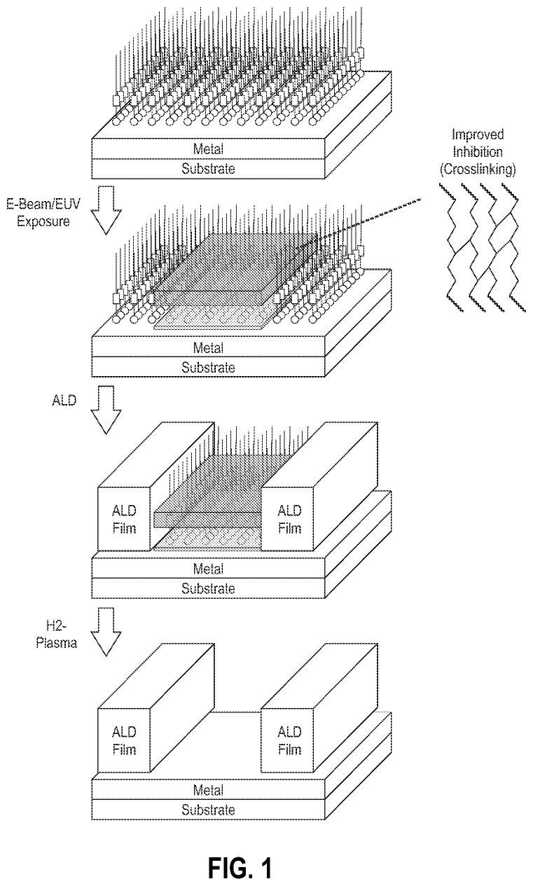

FIG. 1 schematically illustrates the fabrication of a negative tone EUV mask with a hydroxamic acid monolayer upon an Ru-capped Mo/Si multilayer substrate, the crosslinking of the hydroxamic acid with e-beam patterning of the monolayer, the atomic layer deposition of the high NA EUV absorbers Pt or Te in a negative tone, and the removal of the crosslinked regions of the negative tone EUV mask via H₂ plasma.

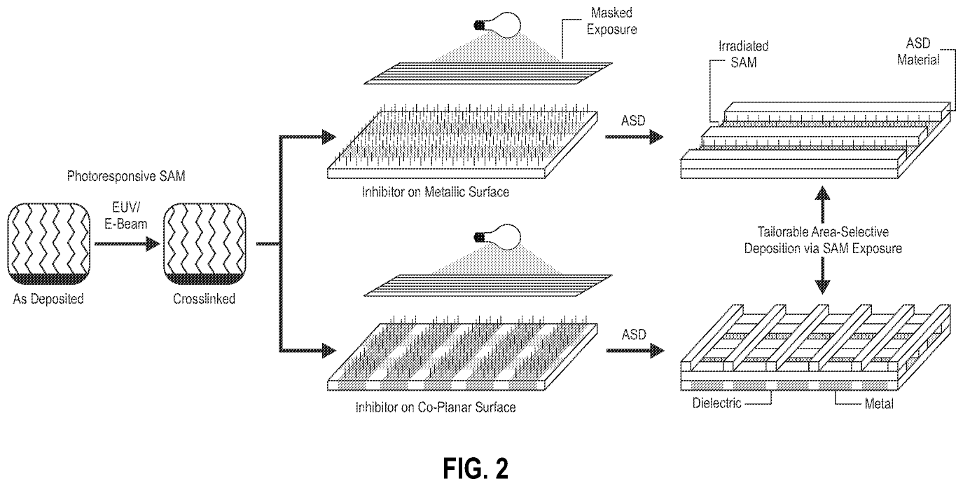

FIG. 2 schematically illustrates how the negative tone resist described herein may be tailored based upon the planar configuration of the substrate surface. The negative tone process shown in FIG. 1 produces a barrier-type negative tone pattern (upper panel), whereas application of the negative tone process on a co-planar surface produces a grid-type negative tone pattern.

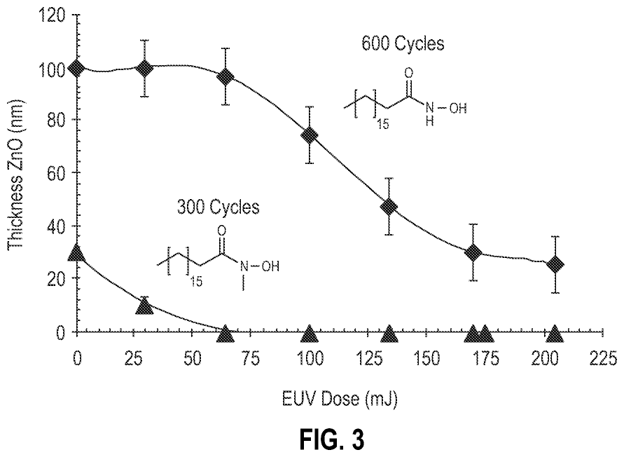

FIG. 3 is a resist contrast curve prepared using Rutherford backscattering spectroscopy (RBS) for two negative tone EUV masks prepared with the EUV absorber zinc oxide (ZnO). One resist was fabricated with a SAM of unsubstituted hydroxamic acid and 600 cycles of ALD with ZnO and the other was fabricated with a SAM of methyl-hydroxamic acid and 300 cycles of ALD with ZnO. Both resists were exposed to EUV dosages ranging from 0-205 mJ. The resist fabricated with the unsubstituted hydroxamic acid saw the greatest contrast between the exposed (<0 mJ/cm² EUV) and unexposed (0 mJ/cm² EUV) regions of the mask at an EUV dosage of 205 mJ/cm². The resist fabricated with the methyl-hydroxamic acid saw maximum contrast between the exposed and unexposed regions of the mask at an EUV range of 70 mJ/cm², which remained constant through an exposure dose of 205 mJ/cm².

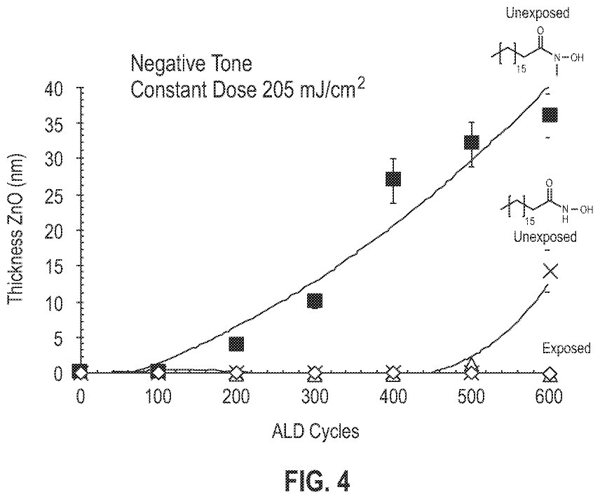

FIG. 4 is a graph showing the results of atomic layer deposition at a constant dose of 205 mJ/cm² of the EUV absorber zinc oxide (ZnO) on two negative tone resists, one resist fabricated with a SAM of unsubstituted hydroxamic acid and the other with a SAM of methyl-hydroxamic acid. The rate of growth of the ZnO over 600 ALD cycles is shown for the exposed and unexposed areas of each resist. The thickness of the ZnO grew from 0-40 nm on the unexposed (i.e., uncrosslinked) region of the negative tone resist prepared with the methyl-hydroxamic acid and the thickness of the ZnO grew from 0-15 nm on the unexposed regions of the negative tone resist prepared with the unsubstituted hydroxamic acid. In both resists, the ZnO did not grow on the exposed (i.e., crosslinked) regions of the SAMs.

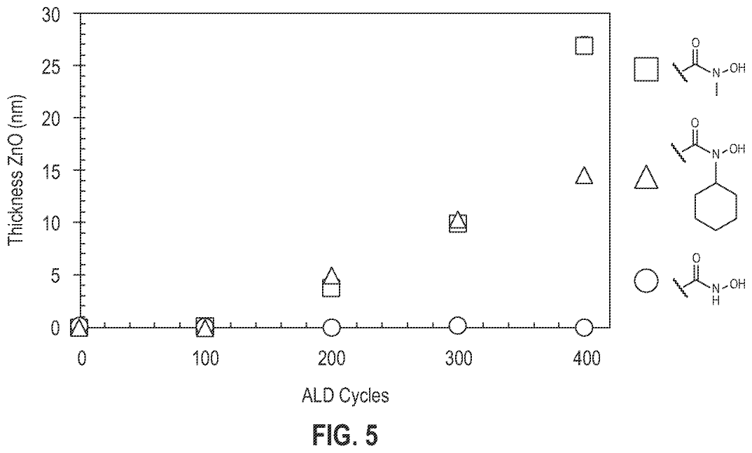

FIG. 5 is a graph showing the results of atomic layer deposition of ZnO on three negative tone patterned resists, one fabricated with a SAM of unsubstituted hydroxamic acid and not exposed to EUV radiation, the other with a SAM of methyl-hydroxamic acid and EUV exposure at 205 mJ/cm², and the third with a SAM of cyclohexyl-hydroxamic acid and EUV exposure at 205 mJ/cm². The unsubstituted hydroxamic acid SAM, which was not exposed to EUV radiation, shows no growth after 500 ALD cycles whereas the exposed methyl-hydroxamic acid shows ZnO growth to 27 nm after 400 ALD cycles and the exposed cyclohexyl-hydroxamic acid shows ZnO growth to 14.6 nm after 400 ALD cycles.

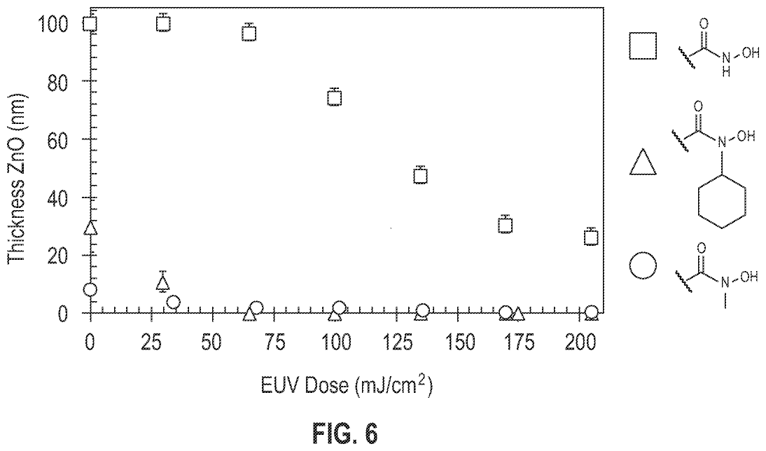

FIG. 6 is a resist contrast curve prepared using RBS on three ZnO negative tone resists, one fabricated with a SAM of unsubstituted hydroxamic acid, the other with a SAM of methyl-hydroxamic acid, and the third with a SAM of cyclohexyl-hydroxamic acid, all of which were exposed to EUV dosages ranging from 0-200 mJ. The RBS was used to measure the ZnO thickness in nm at different EUV dosages. The resist fabricated with the unsubstituted hydroxamic acid SAM saw the greatest contrast between the exposed and unexposed regions of the mask at an EUV dosage of 205 mJ/cm². The resist fabricated with the methyl-hydroxamic acid SAM saw maximum contrast between the exposed and unexposed regions of the mask at an EUV range of 70 mJ/cm², which remained constant through an exposure dose of 205 mJ/cm². The resist fabricated with the cyclohexyl-hydroxamic acid SAM saw maximum contrast between the exposed and unexposed regions of the mask at an EUV range of 65, which remained relatively constant through an exposure of 205 mJ/cm². The contrast curve results for the unsubstituted hydroxamic acid SAM and the methyl-hydroxamic acid SAM are consistent with those in FIG. 3.

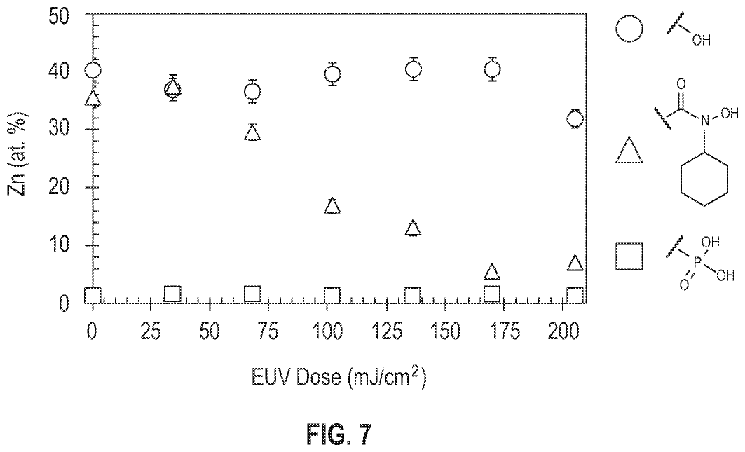

FIG. 7 is a resist contrast curve prepared using x-ray photoelectron spectroscopy (XPS) on three negative tone resists fabricated, one fabricated with a SAM of cyclohexyl-hydroxamic acid, the other fabricated with a monolayer of phosphonic acid, and the third fabricated with a monolayer of octadecanethiol (ODT), all of which were exposed to EUV dosages ranging from 0-205 mJ/cm². The XPS was used to measure the percentage of ZN at different EUV dosages. The resist fabricated with the cyclohexyl-hydroxamic SAM saw maximum contrast between the exposed and unexposed regions of the mask at 205 mJ/cm². The resist fabricated with the phosphonic acid showed no adherence of the ZnO to the phosphonic acid and thus, failed to produce an EUV mask. The resist fabricated with the ODT showed adherence of ZnO to the ODT, but did not show any meaningful change in the percentage of ZnO at any EUV dosage. FIG. 7 shows that unlike phosphonic acid and ODT, the hydroxamic acid SAMs described herein produce functioning EUV masks.

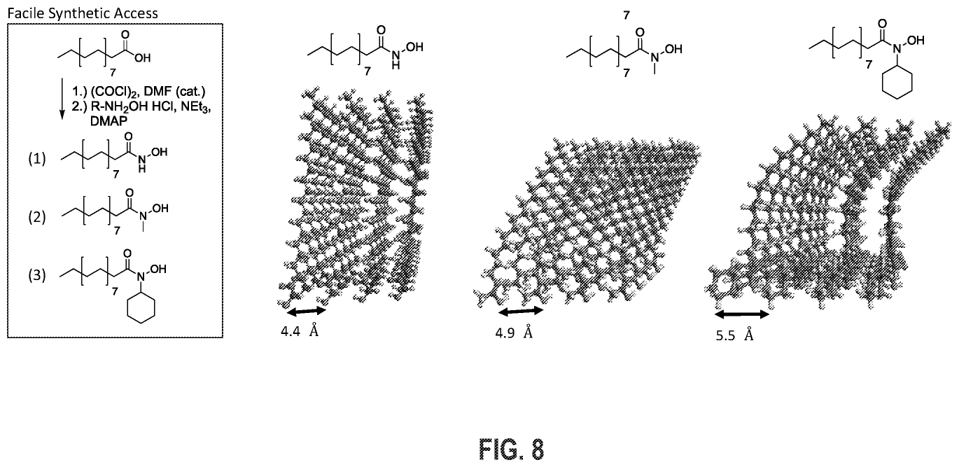

FIG. 8 is a schematic illustration of the different packing densities of hydroxamic acid, methyl-hydroxamic acid, and cyclohexyl-hydroxamic acid.

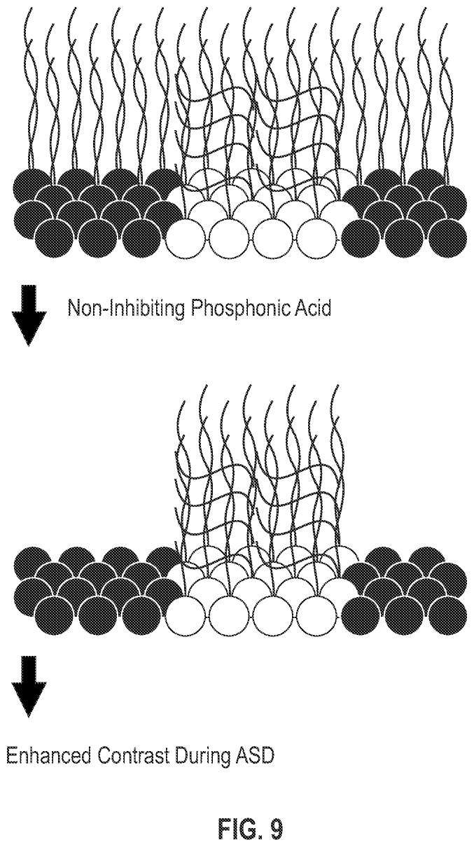

FIG. 9 is a schematic illustration of how phosphonic acid increases the contrast of a hydroxamic acid self-assembled monolayer during area selective deposition. The phosphonic acid displaces uncrosslinked hydroxamic acids from the surface of the SAM in the unexposed crosslinked regions of the SAM thus increasing the contrast between the unexposed and exposed regions of the SAM during ASD.

In a further embodiment, the EUV mask has a positive tone, silanes are used for the self-assembled monolayer, and e-beam and/or EUV radiation (referred to collectively as “exposure”) is used for the patterning. Since the non-reactive silane molecule tail is rendered reactive through the generation of a polar group upon exposure, pattern-wise exposure of a silane SAM results in the exposed regions becoming reactive while the non-exposed regions remain unreactive. When the EUV absorber is deposited onto the irradiated and/or optically treated SAM, the EUV absorber grows only on the areas of the SAM that have been exposed. Any suitable substrate may be used to generate positive tone EUV masks with silanes; examples of substrate materials, including, without limitation, silicon, silicon dioxide, ruthenium, molybdenum, and combinations thereof.

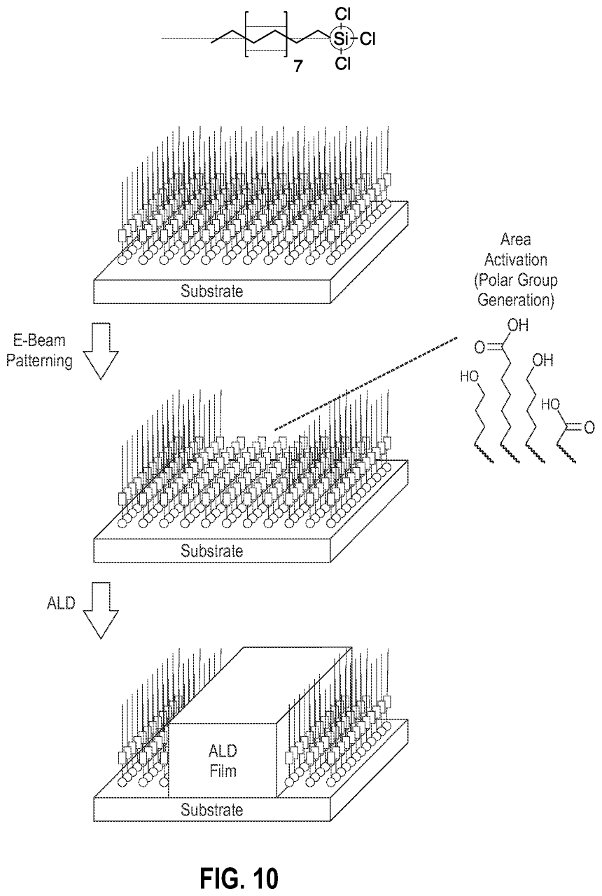

FIG. 10 schematically illustrates the fabrication of a positive tone EUV mask with a silane monolayer upon a substrate, the e-beam patterning of the monolayer to activate the non-reactive tail of the silane through polar group generation, and the atomic layer deposition of the high NA EUV absorber Pt or Te in a positive tone.

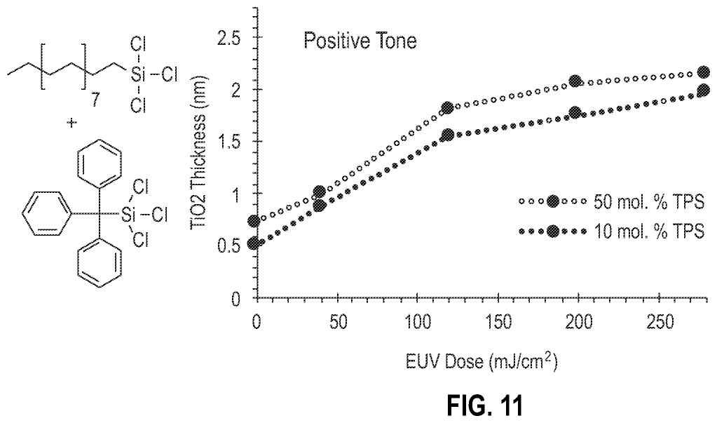

FIG. 11 is a resist contrast curve graph for two positive tone EUV masks prepared with the EUV absorber titanium dioxide (TiO₂). One resist was fabricated with a SAM of 50 mol % trichloro(octadecyl)silane and 50 mol % trichlorophenylsilane (TPS) and the other resist was fabricated with a SAM of 90 mol % trichloro(octadecyl)silane and 10 mol % TPS. Both resists were exposed to EUV dosages ranging from 0-280 mJ/cm². Both positive tone resists saw the greatest contrast between the exposed (<0 mJ/cm² EUV) and unexposed (0 mJ/cm² EUV) regions of the mask at an EUV dosage of 280 mJ/cm² with the 50 mol % TPS resist having a slightly thicker TiO₂ thickness (ranging from ˜ 0.1-0.3 nm greater thickness) at each EUV dosage in comparison to the 10 mol % TPS resist.

In another embodiment, the EUV mask has a positive tone, PAGs are used for the self-assembled monolayer, and e-beam and/or EUV radiation is used for the patterning. PAGs self-assemble on a substrate surface as a polymer brush monolayer. A polymer brush comprises an assembly tethered long chain molecules that are attached to a substrate at one end and at the other end, stretch away from the substrate. As a block polymer, polymer brushes behave differently from free polymer chains. Upon exposure to e-beam and/or EUV radiation, the non-reactive tail of the PAG polymer brush is transformed to a polar acid. Any suitable substrate may be used to generate positive tone EUV masks with PAGs. Examples of substrate materials for the positive tone masks include, without limitation, silicon, silicon dioxide, ruthenium, molybdenum, and combinations thereof.

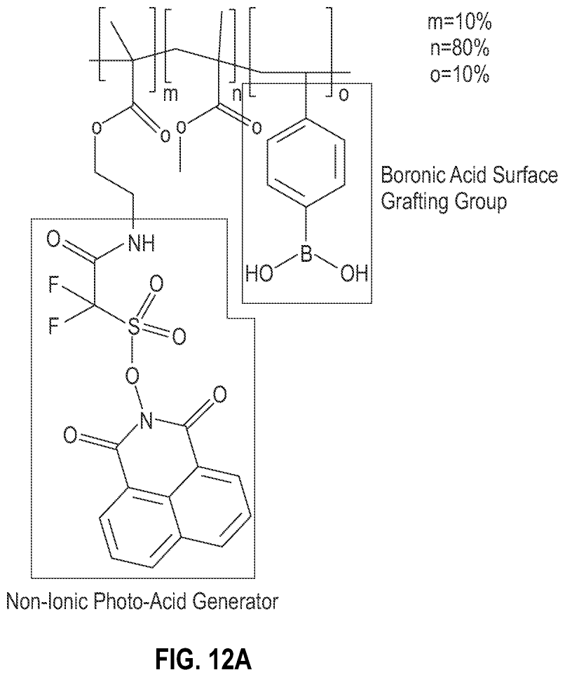

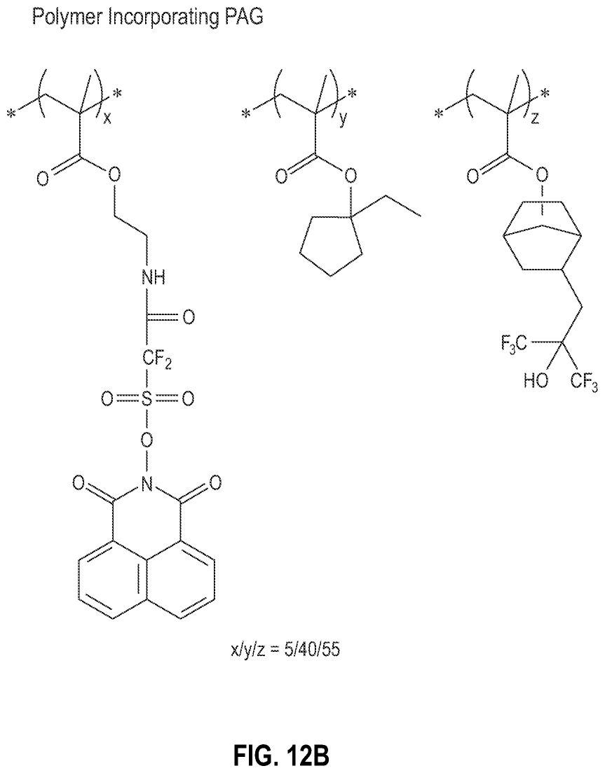

FIG. 12A is a diagram of a non-ionic PAG and FIG. 12B is a diagram of a polyacrylate polymer incorporating the PAG of FIG. 12A.

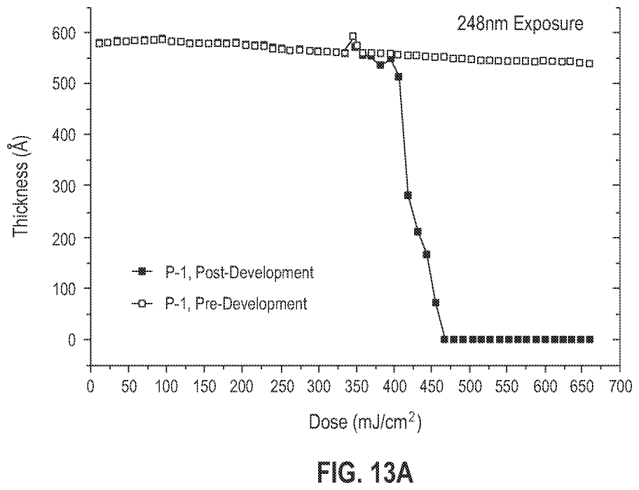

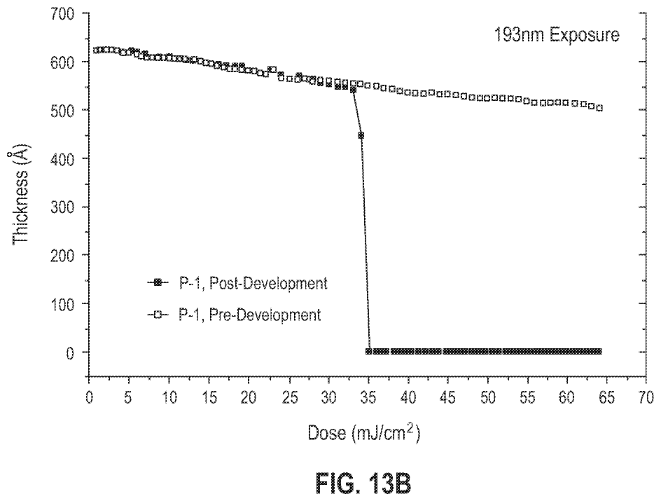

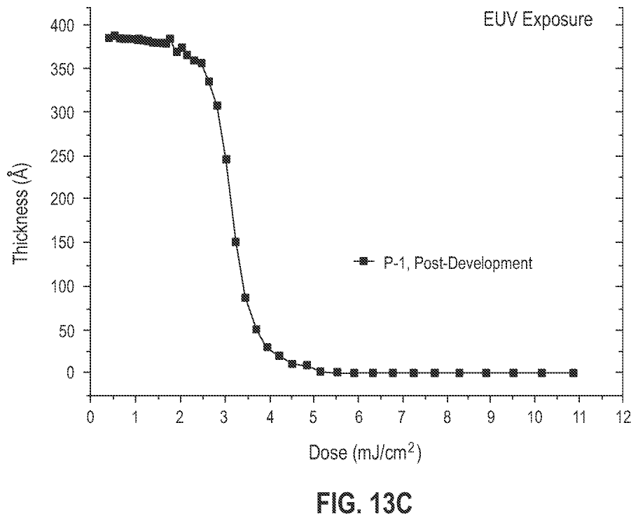

FIG. 13A-13C are contrast curves for resists fabricated with the non-ionic PAG polymer of FIG. 12B at 193 nm exposure pre- and post-development (FIG. 13A), 248 nm exposure pre- and post-development (FIG. 13B), and EUV exposure post-development (FIG. 13C). At 248 nm exposure post-development, the thickness of the PAG SAM falls from 575 to 0 A at a dosage range of 400-450 mJ/cm²; at 193 nm exposure post-development, the thickness of the PAG SAM falls from 625 to 0 A at a dosage of 35 mJ/cm²; and with EUV exposure post-development, the thickness of the PAG SAM falls from 385 to 1 A at a dosage range of 3-5 mJ/cm². The results show increased sensitivity of the non-ionic PAG at EUV exposure versus 248 and 193 exposures.

The descriptions of the various aspects and/or embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the aspects and/or embodiments, the practical application or technical improvement over technologies found in the marketplace, or to enable others of ordinary skill in the art to understand the aspects and/or embodiments disclosed herein.

### EXPERIMENTAL

The following examples are set forth to provide those of ordinary skill in the art with a complete disclosure of how to make and use the aspects and embodiments of the invention as set forth herein. While efforts have been made to ensure accuracy with respect to variables such as amounts, temperature, etc., experimental error and deviations should be considered. Unless indicated otherwise, parts are parts by weight, temperature is degrees Centigrade, and pressure is at or near atmospheric. All components were obtained commercially unless otherwise indicated.

### Example 1

### A Negative Tone EUV Mask Fabricated with a Hydroxamic Acid Self-Assembled Monolayer

A ruthenium (Ru) capped molybdenum-silicon (Mo/Si) multilayer structure was immersed in a solution of a hydroxamic acid of about 0.1 wt. % in 4-methyl-2-pentanol for a period not longer than 30 minutes. The surface was then rinsed with 4-methyl-2-pentanol and dried under N₂. To produce a negative tone EUV mask, the monolayer coated surface then underwent patternwise e-beam radiation (EUV radiation could also be used for this step), which crosslinked the hydroxamic acid only in the areas that were exposed to the e-beam radiation. The patterned monolayer was next submitted to ZnO, produced from half cycles of diethyl zinc and water, in an atomic layer deposition process where the film only grew in regions that were not crosslinked and no growth occurred on the crosslinked regions of the monolayer leaving a negative tone EUV mask (Pt, TiO₂, or Te atomic layer deposition would also work for this step). After atomic layer deposition, the residual crosslinked self-assembled monolayer was removed by H₂-plasma.

### Example 2

### A Positive Tone EUV Mask Fabricated with a Silane Self-Assembled Monolayer

A ruthenium (Ru) capped molybdenum-silicon (Mo/Si) multilayer structure is immersed in a solution of octadecyltriethoxysilane in toluene (1 wt. % solution) for approximately 30 minutes at which time, the reactive silane reacts with the substrate surface to form a self-assembled monolayer. The substrate surface with the bound silane is then rinsed with toluene followed by 4-methyl-2-pentanol and dried under N₂. To produce a positive tone EUV mask, the monolayer coated surface undergoes patternwise e-beam or EUV radiation followed by exposure to ambient air where the combination of the irradiation and the oxygen exposure activates the non-reactive tail of the silane to generate reactive polar groups with at least one —OH and/or —COOH group. The patterned monolayer is next submitted to ZnO, Pt, TiO₂, or Te atomic layer deposition where the film grows upon the reactive polar groups leaving a positive tone EUV mask. After atomic layer deposition, any residual aminosilane that did not bind to the substrate or that was not activated by the irradiation is removed via H₂ plasma.

### Example 3

### A Positive Tone EUV Mask Fabricated with a Photoacid Generator Self-Assembled Monolayer

A ruthenium (Ru) capped molybdenum-silicon (Mo/Si) multilayer structure is immersed in a solution of the ionic PAG, 1,8-naphthalamide sulfonate, for approximately 30 minutes at which time the ionic PAG binds to the substrate surface. The substrate surface with the bound ionic PAG is then rinsed with 4-methyl-2-pentanol and dried under N₂. To produce a positive tone EUV mask, the monolayer coated surface undergoes patternwise e-beam or EUV radiation, which generates reactive H⁺ polar acid groups on the monolayer surface. The patterned monolayer is next submitted to ZnO, Pt, TiO₂, or Te atomic layer deposition where the film grows upon the reactive polar acid groups leaving a positive tone EUV mask. After atomic layer deposition, any residual PAG that did not bind to the substrate or that was not activated by the irradiation is removed via H₂ plasma.

We claim:

1. A composition comprising:
a substrate with a top surface and a bottom area;
a self-assembled monolayer adhered to the top surface of the substrate, wherein the self-assembled monolayer comprises a surfactant or a photoacid generator; and
an extreme ultraviolet (EUV) absorbing film comprising at least one EUV absorbing material, wherein the EUV absorbing material binds to the self-assembled monolayer in a negative or positive tone pattern.

2. The composition of claim 1, wherein the substrate is a metal capped substrate and the surfactant has 3-24 C atoms, a polar head group that chelates to the metal cap of the substrate, and a non-polar tail that binds the EUV absorbing material in a negative tone pattern.

3. The composition of claim 1, wherein the self-assembled monolayer has crosslinked and non-crosslinked regions, wherein the EUV absorbing material only adheres to the non-crosslinked regions of the self-assembled monolayer in a negative tone pattern.

4. The composition of claim 1, wherein the surfactant is an organosilicon compound with a reactive head that adheres to the substrate and a polar tail that binds the EUV absorbing material in a positive tone pattern.

5. The composition of claim 1, wherein the photoacid generator is a polymer brush with a reactive head that adheres to the substrate and a polar tail that binds the EUV absorbing material in a positive tone pattern.

6. The composition of claim 1, wherein the EUV absorbing material is selected from the group consisting of platinum, tellurium, zinc, titanium, antimony, indium, bismuth, silver, and combinations thereof.

7. A method for fabricating a positive or negative extreme ultraviolet (EUV) mask comprising:
depositing a surfactant or a photoacid generator on a substrate, wherein the surfactant and/or photoacid generator self-aligns on a surface of the substrate to form a monolayer;
exposing the monolayer to patternwise electron beam or EUV radiation to form a resist pattern; and
depositing an EUV absorbing material onto the monolayer wherein the EUV absorbing material binds to unexposed areas of the monolayer to form a negative patterned EUV mask or exposed areas of the monolayer to form a positive patterned EUV mask.

8. The method of claim 7, wherein the substrate is a metal capped substrate and the surfactant has 3-24 C atoms, a polar head group that chelates to the metal cap of the substrate, and a non-polar tail that binds to the EUV absorbing material in a negative tone pattern.

9. The method of claim 7, wherein the self-assembled monolayer has crosslinked and non-crosslinked regions, wherein the EUV absorbing material only binds to the non-crosslinked regions of the self-assembled monolayer in a negative tone pattern.

10. The method of claim 7, wherein the surfactant is an organosilicon compound with a reactive head that adheres to the substrate and a polar tail that binds the EUV absorbing material in a positive tone pattern.

11. The method of claim 7, wherein the photoacid generator is a polymer brush with a reactive head that adheres to the substrate and a polar tail that binds the EUV absorbing material in a positive tone pattern.

12. The method of claim 7, wherein the EUV absorbing material is selected from the group consisting of platinum, tellurium, zinc, titanium, antimony, indium, bismuth, silver, and combinations thereof.

13. A method for fabricating a negative tone extreme ultraviolet (EUV) mask comprising:
depositing a hydroxamic acid comprising a polar head group and a non-polar tail on a substrate comprising a metal surface, wherein the hydroxamic acid self-aligns to form a monolayer via reaction of the polar head group of the hydroxamic acid with the metal surface of the substrate;
exposing the monolayer to pattern-wise electron beam (e-beam) or EUV radiation, wherein regions of the monolayer exposed to the e-beam or EUV radiation are crosslinked and regions not exposed to the e-beam or EUV radiation are uncrosslinked; and
depositing an EUV absorbing material onto the monolayer, wherein the EUV absorbing material binds to the non-polar tail of the hydroxamic acid on the unexposed and uncrosslinked regions of the monolayer to form a negative tone EUV mask.

14. The method of claim 13, wherein the metal surface of the substrate is selected from the group consisting of ruthenium, palladium, platinum, titanium, tantalum, nickel, copper, aluminum, and combinations thereof.

15. The method of claim 13, wherein the hydroxamic acid is selected from the group consisting of unsubstituted hydroxamic acid, methyl-hydroxamic acid, tetra-hydroxamic acid, hexyl-hydroxamic acid, octyl-hydroxamic acid, cyclohexyl-hydroxamic acid, octadecyl-hydroxamic acid, dodecyl-hydroxamic acid, and combinations thereof.

16. The method of claim 13, wherein the hydroxamic acid further comprises reactive groups selected from the group consisting of alkenes, alkynes, glycidyls, and combinations thereof.

17. The method of claim 13, wherein the crosslinked regions of the monolayer are removed from the negative tone EUV mask with a reducing agent selected from the group consisting of H₂ plasma, N₂ plasma, NH₃ plasma, and combinations thereof.

18. The method of claim 13, wherein the negative tone of the EUV mask is enhanced with a compound selected from the group consisting of phosphonic acid, phosphonic acid derivatives, stearic acid, stearic acid derivatives, and combinations thereof.

19. The method of claim 13, wherein the EUV absorbing material is selected from the group consisting of platinum, tellurium, zinc, titanium, antimony, indium, bismuth, silver, and combinations thereof.

20. A method for fabricating a positive tone extreme ultraviolet (EUV) mask comprising:
depositing a silane on a substrate, wherein the silane has head groups that are reactive and tails that are non-reactive and the silane self-aligns to form a monolayer via reaction of the head groups to a top surface of the substrate;
treating the monolayer with pattern-wise electron beam or EUV radiation, wherein the e-beam or EUV radiation activates the tails of the silane through generation of a polar group on the tails of the silane only in regions of the monolayer exposed to the e-beam or EUV radiation; and
depositing an EUV absorbing material onto the treated monolayer, wherein the EUV absorbing material binds to the polar group of the silane tails to form a positive tone EUV mask.

21. The method of claim 20, wherein the silane is selected from the group consisting of aminosilanes, ethoxysilanes, chlorosilanes, glycidoxysilanes, methacryloxysilanes, methoxysilanes, N-alkyl-silanes, mercaptosilanes, and combinations thereof.

22. A method for fabricating a positive tone extreme ultraviolet (EUV) mask comprising:
depositing a photoacid generator (PAG) on a substrate, wherein the PAG has head groups that are reactive and tails groups that are non-reactive and the PAG self-aligns to form a polymer brush monolayer via reaction of the head groups to a top surface of the substrate;
treating the PAG with patternwise EUV radiation, wherein the EUV radiation activates the tail groups of the PAG through generation of a polar acid on the tail groups of the PAG only in regions of the polymer brush monolayer exposed to the EUV radiation; and
depositing an EUV absorbing material onto the treated polymer brush monolayer, wherein the EUV absorbing material binds to the polar acid of the PAG tail groups to form a positive tone EUV mask.

23. The method of claim 22, wherein the PAG is an ionic PAG selected from the group consisting of diaryliodonium salts, triarylsulfonium salts, and naphthalimide sulfonates, and combinations thereof.

24. The method of claim 22, wherein the PAG is a non-ionic PAG selected from the group consisting of iminosulfonates, imidosulfonates, benzyl sulfonates, and combinations thereof.

25. The method of claim 22, wherein the EUV absorbing material is selected from the group consisting of platinum, tellurium, zinc, titanium, antimony, indium, bismuth, silver, and combinations thereof.
